(19) United States
(12) Patent Application Publication
(10) Pub. No.: US 2014/0318596 A1
(43) Pub. Date: Oct. 30, 2014

(54) DEVICES, SYSTEMS AND METHODS FOR ELECTROMAGNETIC ENERGY COLLECTION

(71) Applicant: PACIFIC INTEGRATED ENERGY, INC., San Diego, CA (US)

(72) Inventors: Bala Krishna Juluri, San Diego, CA (US); Justin Hallas, San Diego, CA (US); Phillip Layton, San Diego, CA (US); Michael Fennel, San Diego, CA (US); Shawn Meade, San Diego, CA (US)

(21) Appl. No.: 14/357,941

(22) PCT Filed: Nov. 13, 2012
(86) PCT No.: PCT/US12/64872

§ 371 Date: May 13, 2014

Related U.S. Application Data
(60) Provisional application No. 61/559,583, filed on Nov. 14, 2011.

(51) Int. Cl. H01L 31/0352

(52) U.S. Cl. CPC H01L 31/035209
USPC 136/244; 136/255

(57) ABSTRACT

A system for collecting electromagnetic energy is provided. The system can include one or more electromagnetic energy collection devices. An individual device comprises a first electrically conductive layer adjacent to a semiconductor layer. The first electrically conductive layer forms a Schottky barrier to charge flow at an interface between the first electrically conductive layer and the semiconductor layer. A second electrically conductive layer is disposed adjacent to the semiconductor layer and away from the first electrically conductive layer. The second electrically conductive layer forms an ohmic contact with the semiconductor layer. Upon exposure of the device to electromagnetic energy, the first electrically conductive layer generates localized surface plasmon resonances that resonantly interact with the second electrically conductive layer, providing near perfect absorption of light. The absorption of light creates hot electrons in the first layer that cross the Schottky barrier to drive an external load.

### CROSS-REFERENCE

This application claims the benefit of U.S. Provisional Application No. 61/559,583, filed Nov. 14, 2011, which application is entirely incorporated herein by reference.

### BACKGROUND

Photovoltaics (PV) is a method of generating electrical power by converting solar radiation into direct current electricity using semiconductors that exhibit the photovoltaic effect. Photovoltaic power generation can employ solar panels composed of a number of solar cells containing a photovoltaic material.

Traditional inorganic photovoltaics (PV) use a semiconductor p-n junction to absorb light, create free-carriers and transport those carriers to generate power. An alternative method to convert light into electric energy is by internal photo-emission of hot electrons over a Schottky barrier. See, e.g., E. W. McFarland and J. Tang, “A photovoltaic device structure based on internal electron emission,” Nature, vol. 421, no. 6923, pp. 616-8, February 2003, which is entirely incorporated herein by reference.

### SUMMARY

Recognized herein are various limitations with devices currently available for converting light into electric (or electrical) energy. For instance, a device having a Schottky diode composed of thin gold layer on titanium dioxide may convert light into electric energy by internal photo-emission, but such a device may be limited by various competing processes, such as charge transfer from metal to dye, dye luminescence and non-radiative de-excitation by coupling to phonons. Although some devices may include metallic nanostructures, metallic nanostructures may exhibit strong optical resonances due to collective oscillations of electrons (known as plasmons) that result in strong absorption and scattering of light. Devices that operate by internal photo-emission may use hot electron flow from metal nanostructures instead of dyes over a Schottky barrier for harnessing and sensing light, but such devices may convert only a small portion of the incident energy into hot electrons; a significant part of the energy of a plasmon decays radiatively and is lost.

This disclosure provides devices, systems and methods for efficiently coupling light by internal photo-emission to produce hot electrons that can be utilized, for example, for power production or photo-detection. In some embodiments, in the first stage, hot electrons are produced in conducting structures by combined electric and magnetic resonances that can allow nearly complete absorption of light. In a second stage, the hot electrons are transferred over a Schottky barrier, either via internal photo-emission or direct tunneling. In addition to providing for strong absorption, this method also enables photon capture over a broad spectral bandwidth or in narrow wavelength bands determined by device geometry and material composition. Narrow wavelength absorbers can be tuned to have single or multiple absorption bands. Devices based on this concept can be designed such that the absorption is independent of incident polarization and angle. These designs lend themselves to a substantially thin form factor and can be readily extended to flexible and conformal sensors and energy harvesters.

An aspect of the disclosure provides a device for collecting electromagnetic energy. The device comprises a first layer comprising electrically conductive nanostructures. The first layer is adapted to generate hot electrons upon exposure to electromagnetic energy. The device comprises a second layer adjacent to the first layer. The second layer comprises a semiconductor material. An interface between the first and second layers comprises a Schottky barrier to charge flow upon exposure of the device to electromagnetic energy. The device further includes a third layer adjacent to the second layer. The third layer comprises an electrically conductive material. Upon exposure of the device to electromagnetic energy, the nanostructures in the first layer generate localized surface plasmon resonances that resonantly interact with the third layer to produce power.

In an embodiment, upon exposure of the device to electromagnetic energy, combined responses of the first layer and the third layer results in a resonant electric response to impinging electromagnetic energy from the direction of the first layer. In another embodiment, the third layer forms a Schottky contact with the second layer. In another embodiment, the third layer forms an ohmic contact with the second layer. In another embodiment, the device further comprises an electrode that is adjacent to the second and third layers. The electrode can be laterally adjacent to the second layer, and the electrode can form an ohmic contact with the second layer.

In an embodiment, the third layer forms an ohmic contact with the second layer. In another embodiment, the device further comprises a fourth layer adjacent to the third layer. The fourth layer can form electric and magnetic resonances with the first layer.

In another embodiment, the electrically conductive nanostructures of the first layer and/or the electrically conductive material of the third layer include one or more materials selected from the group consisting of aluminum, silver, gold, copper, platinum, nickel, copper, iron, tungsten, yttrium oxide, palladium oxide, graphite and graphene. In another embodiment, the semiconductor material includes one or more materials selected from the group consisting of titanium oxide, tin oxide, zinc oxide, silicon, diamond, germanium, silicon carbide, gallium nitride, cadmium telluride.

In an embodiment, the electrically conductive nanostructures of the first layer are included in a plurality of elongate rows. In another embodiment, the electrically conductive nanostructures of the first layer are included in one or more three-dimensional pillars. An individual pillar of the one or more three-dimensional pillars can have a height to width ratio greater than one. In another embodiment, the individual pillar has a taper angle between about 50 degrees and 90 degrees in relation to a base of the individual pillar. In another embodiment, the individual pillar has an aspect ratio of at least about 2:1. In another embodiment, the individual pillar has an aspect ratio of at least about 10:1.

In an embodiment, the first layer is optically transparent. In another embodiment, the device further comprises a fourth layer adjacent to the first layer. The fourth layer can comprise a semiconductor material. In another embodiment, the first layer comprises one or more probe molecules adsorbed on an exposed surface of the first layer. The one or more probe molecules can be adapted to (i) interact with an analyte in a solution that is in contact with the first layer and (ii) modulate power generated in and/or current flow through the device. In an embodiment, the first layer comprises a matrix of nanoparticles. In another embodiment, individual nanoparticles of the of the first layer has particle sizes from about 1 nanometer (nm) to 100 nm. In one embodiment the nanoparticles are comprised of one or more materials selected from the group consisting of aluminum, silver, gold, copper, platinum, nickel, copper, iron, tungsten, yttrium oxide, palladium oxide. In another embodiment, the matrix includes one or more materials selected from the group consisting of titanium oxide, tin oxide, zinc oxide, silicon, diamond, germanium, silicon carbide, gallium nitride, cadmium telluride.

In an embodiment, the second layer has a thickness from about 1 nanometer (nm) to 500 nm. In another embodiment, the electrically conductive nanostructures are disposed in a patterned array in the first layer.

In an embodiment, the first layer comprises one or more openings extending through the first layer. In another embodiment, portions of the second layer are exposed through the one or more openings of the first layer. In another embodiment, the third layer is isolated from the first layer.

Another aspect of the disclosure provides a system for collecting electromagnetic energy. The system comprises one or more electromagnetic energy collection devices. An individual electromagnetic energy collection device comprises a first electrically conductive layer adjacent to a semiconductor layer. The first electrically conductive layer forms a Schottky barrier to charge flow at an interface between the first electrically conductive layer and the semiconductor layer. The device further comprises a second electrically conductive layer adjacent to the semiconductor layer and disposed away from the first electrically conductive layer. The second electrically conductive layer forms (i) an ohmic contact with the semiconductor layer, or (ii) a Schottky barrier to charge flow at an interface between the second electrically conductive layer and the semiconductor layer. Upon exposure of the device to electromagnetic energy, the first electrically conductive layer generates localized surface plasmon resonances that resonantly interact with the second electrically conductive layer to produce power.

In an embodiment, the semiconductor layer has a thickness from about 1 nanometer (nm) to 500 nm. In another embodiment, the semiconductor layer has a thickness from about 1 nm to 100 nm.

In an embodiment, the second electrically conductive layer forms a Schottky barrier to charge flow at the interface between the second electrically conductive layer and the semiconductor layer. In another embodiment, the system comprises a plurality of electromagnetic energy collection devices. In another embodiment, the electromagnetic energy collection devices are electrically coupled to one another in series. In another embodiment, upon exposure of the system to electromagnetic energy, combined responses of the first electrically conductive layer and the second electrically conductive layer results in a resonant electric response to impinging electromagnetic energy from the direction of the first electrically conductive layer. In another embodiment, the device further comprises a contact that is adjacent to the semiconductor layer and the second electrically conductive layer. The contact can be laterally disposed in relation to the semiconductor layer. The contact can form an ohmic contact with the semiconductor layer.

In an embodiment, the first electrically conductive layer includes electrically conductive nanostructures. In another embodiment, the electrically conductive nanostructures and/or the second electrically conductive layer include one or more materials selected from the group consisting of aluminum, silver, gold, copper, platinum, nickel, copper, iron, tungsten, yttrium oxide, palladium oxide, graphite and graphene.

In an embodiment, the electrically conductive nanostructures are included in a plurality of elongate rows. In another embodiment, the electrically conductive nanostructures are included in one or more three-dimensional pillars. An individual pillar of the one or more three-dimensional pillars can have a height to width ratio greater than one. In another embodiment, the individual pillar has a taper angle between about 50 degrees and 90 degrees in relation to a base of the individual pillar. In another embodiment, the individual pillar has an aspect ratio of at least about 2:1. In another embodiment, the individual pillar has an aspect ratio of at least about 10:1. In another embodiment, individual nanostructures of the electrically conductive nanostructures have particle sizes from about 1 nanometer (nm) to 100 nm.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 shows an energy band diagram of a device of the disclosure.

FIG. 2a schematically illustrates a device in a narrow band sensor configuration. FIG. 2b shows a close-up of a pillar of the device of FIG. 2a.

FIG. 3 is an example of computer simulations of optical absorption, reflection and transmission of the device of FIG. 2.

FIG. 4 schematically shows a device with a crossbar configuration.

FIG. 5 schematically shows a device with a top layer comprising metal nanoparticle aggregates.

FIG. 6 schematically illustrates a high-aspect ratio broad-bandwidth energy collector.

FIG. 7 is an example of a computer simulation showing optical absorption, reflection and transmission of the device of FIG. 6.

FIG. 8a schematically illustrates a high-aspect ratio broad-bandwidth energy collector with a top ohmic layer. FIG. 8b is a close-up of a pillar of the device of FIG. 8a.

FIG. 9 schematically illustrates a device that can be used as a bio-sensor or chemical sensor.

FIG. 10 illustrates a process flow for forming an electromagnetic energy collection device.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “hot electron,” as used herein, generally refers to non-equilibrium electrons (or holes) in a semiconductor. This term can refer to electron distributions describable by the Fermi function, but with an elevated effective temperature. Hot electrons can quantum mechanically tunnel out of the semiconductor material instead of recombining with a hole or being conducted through the material to a collector.

The term “electromagnetic energy,” as used herein, generally refers to electromagnetic radiation (also “light” herein), which is a form of energy exhibiting wave and particle-like behavior. Electromagnetic radiation includes radio waves, microwaves, infrared radiation, visible light, ultraviolet radiation, X-rays and gamma rays. Electromagnetic radiation includes photons, which is the quantum of the electromagnetic interaction and the basic of light.

The term “pitch,” as used herein, generally refers to the center-to-center distance between features, such as, for example, like features. In an example, a pitch is the center-to-center distance between pillars or openings in a material layer.

The term “adjacent to,” as used herein, generally refers to “next to” or “adjoining,” such as in contact with, or in proximity to. A layer, device or structure adjacent to another layer, device or structure is next to or adjoining the other layer, device or structure. In an example, a first layer that is adjacent to a second layer is directly next to the second layer. In another example, a first layer that is adjacent to a second layer is separated from the second layer by a third (intermediate) layer. Adjacent components of any device described herein are in such contact or proximity to each other such that the device functions, such as for a use described herein. In some instances, adjacent components that are in proximity to each other are within 20 micrometers (“microns”) of each other, within 10 microns of each other, within 5 microns of each other, within 1 micron of each other, within 500 nanometers (“nm”) of each other, within 400 nm of each other, within 300 nm of each other, within 250 nm of each other, within 200 nm of each other, within 150 nm of each other, within 100 nm of each other, within 90 nm of each other, within 80 nm of each other, within 75 nm of each other, within 70 nm of each other, within 60 nm of each other, within 50 nm of each other, within 40 nm of each other, within 30 nm of each other, within 25 nm of each other, within 20 nm of each other, within 15 nm of each other, within 10 nm of each other, within 5 nm of each other, or the like. In some instances, adjacent components that are in proximity to each other are separated by vacuum, air, gas, fluid, or a solid material (e.g., substrate, conductor, semiconductor, or the like).

The term “ohmic,” as used herein, generally refers to a material that behaves in accordance with Ohms law, namely V=I*R, where ‘V’ denotes electrical potential, ‘I’ denotes current and ‘R’ denotes resistance.

This disclosure provides devices, systems and methods that can be used to collect electromagnetic energy. In some examples, systems and devices of the disclosure can collect electromagnetic energy with increased total external efficiency in relation to other devices that collect electromagnetic energy based on internal-photoemission.

### Electromagnetic Energy Collection Devices and Systems

An aspect of the disclosure provides a device for collecting or harvesting electromagnetic energy. The device comprises a first layer comprising electrically conductive nanostructures. The first layer is adapted to generate hot electrons upon exposure of the first layer to electromagnetic energy. The first layer can include one or more openings extending through the first layer. The one or more openings can have various shapes and be distributed in various patterns. In some cases, the one or more openings have cross-sections that are circular, triangular, square, rectangular, pentagonal, hexagonal, heptagonal, octagonal, or partial shapes or combinations thereof. The one or more openings can include multiple openings that can be distributed along elongate rows that are parallel to one another, or along a first set of rows that are parallel to one another and a second set of rows that are orthogonal to the first set of rows.

The device can further include a second layer adjacent to the first layer. The second layer can include a semiconductor material. In some situations, portions of the second layer are exposed through the one or more openings of the first layer. An interface between the first and second layers can include a Schottky barrier to charge flow upon exposure of the device to electromagnetic energy.

The device can further include a third layer adjacent to the second layer. The third layer comprises an electrically conductive material. In some cases, upon exposure of the device to electromagnetic energy, nanostructures in the first layer generate localized surface plasmon resonances that resonantly interact with the third layer to produce power.

The first layer can be isolated from the third layer. In an example, the third layer is physically isolated from the first layer. In another example, the first layer is electrically isolated from the first layer. In some cases, the first and third layers are in electrical contact with one another through the second layer.

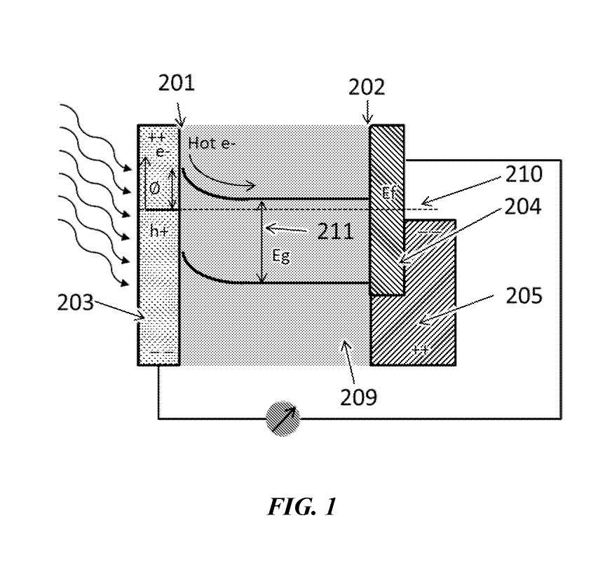

FIG. 1 schematically illustrates an energy collection device. The device of FIG. 1 can be used to collect electromagnetic energy from light, such as solar light (also “solar radiation” herein). The device of FIG. 1 can be used to collect energy to drive an external load, or as in a sensor or a system that includes the device of FIG. 1 coupled to an energy storage system (e.g., battery).

The device of FIG. 1 includes a semiconductor layer 209 between a first layer 203 and a second layer 205. The semiconductor layer 209 can include an n-type semiconductor. The first layer 203 can include patterned nano/micro metallic nanostructures (e.g., nanodots, nanorods, nanowires, nanoparticle aggregates), and the second layer 205 can include a continuous metal film. The semiconductor layer 209 is in electrical contact with an electric conductor 204 that forms an ohmic contact 202 with the semiconductor layer 209. The first layer 203 and the electric conductor 204 provide electrical contacts to the semiconductor layer 209. The first layer 203 and the electronic conductor 204 can be coupled to a load (e.g., power grid, electronic device, energy storage system). The first layer 203 and second layer 205 can form Schottky contacts (e.g., to provide Schottky barriers) with the semiconductor layer 209. In some examples, the material of each for the first layer 203 and the second layer 205 is selected to provide Schottky contacts at an interface between the first layer 203 and the semiconductor layer 209 and an interface between the second layer 205 and the semiconductor layer 209. In other examples, the material of the first layer 203 provides a Schottky contact with semiconductor layer 209, and the second layer 205 has an ohmic contact with the semiconductor layer 209.

The external load can be electrically coupled to the first layer 203 and the second layer 204. In an example, a first terminal (e.g., positive terminal) of the external load is coupled to a first electrode in electrical contact with the first layer 203, and a second terminal of the external load is coupled to a second electrode in electrical contact with the second layer 204.

During operation of the device of FIG. 1, incident light (wavy lines to the left of the nanostructures 203) can be absorbed by the nanostructures of the first layer 203 and the continuous metal film of the second layer 205 due, at least in part, to excitation of electric (plasmon) and magnetic resonances. In some situations, at least about 10%, 20%, 30%, 40%, 50%, 60%, 70%, 80%, 90%, 95%, or 99% of incident light is absorbed by the first layer 203 and the second layer 205. The contact between the first layer 203 and the semiconductor 209 can provide a Schottky contact 201, which can be a Schottky barrier.

In an example, during operation of the device of FIG. 1, absorbed light creates hot electrons (“Hot e-”) upon plasmon decay and these electrons can tunnel through or pass over the Schottky contact 201 (which comprises a Schottky barrier) and subsequently thermalize in the semiconductor 209 into a conduction band of the semiconductor 209. The generation of hot electrons is accompanied by the generation of holes (“h+”). These thermalized electrons can drive the load when collected by the electric conductor 204. Frequencies of light with energies (hv) greater than the Schottky barrier height (φ) can be converted into electric energy to generate power. In configurations where the thickness of the Schottky barrier is relatively small, hot electrons can directly tunnel through the Schottky barrier and drive a load electrically coupled to the device of FIG. 1. In some examples, the device of FIG. 1 can have Schottky barrier heights (φ) of about 0.1 eV to 30 eV, or 0.1 eV to 20 eV, or 0.1 eV to 10 eV.

The semiconductor 209 can be doped or undoped. In some cases, the semiconductor 209 is doped n-type or p-type, while in other cases the semiconductor 209 is intrinsic. In some cases, the semiconductor 209 is doped n-type with the aid of nitrogen or phosphorous, and p-type with the aid of boron or aluminum. The semiconductor 209 has a Fermi level 210 between valence and conduction bands of the semiconductor 209. The valence and conduction bands of the semiconductor 209 are separated by a band gap 211 (“Eg”). In some examples, the band gap is from about 0.1 eV to 10 eV, 0.1 eV to 3.5 eV, or 0.2 eV to 1.0 eV. In some examples, the semiconductor 209 includes TiOx and the band gap is about 3 eV.

This disclosure provides methods for the collection of electromagnetic radiation and the conversion of collected electromagnetic radiation to electric energy. In some embodiments, an energy collection device includes a patterned conducting top contact layer whose geometry is tailored to maximize absorption of incoming light.

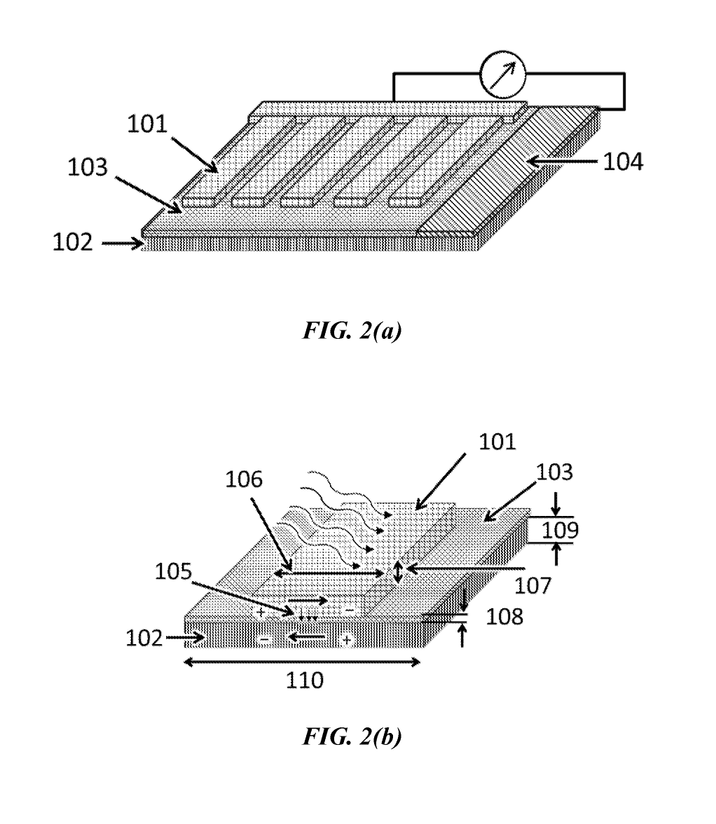

FIGS. 2a and 2b show an example of an energy collection device. In the illustrated examples, the energy collection device can be a sensor. In a sensor configuration, an external bias may be applied to improve light detection. FIG. 2b is a close-up of the device shown in FIG. 2a. The device of FIGS. 2a and 2b includes a top conductor layer 101, bottom conductor layer 102, semiconductor layer 103 disposed between the top conductor layer 101 and bottom conductor layer 102, and a lateral ohmic contact 104. The lateral ohmic contact 104 can be an electrode of the device. The semiconductor layer 103 can form a Schottky contact with the top conductor layer 101.

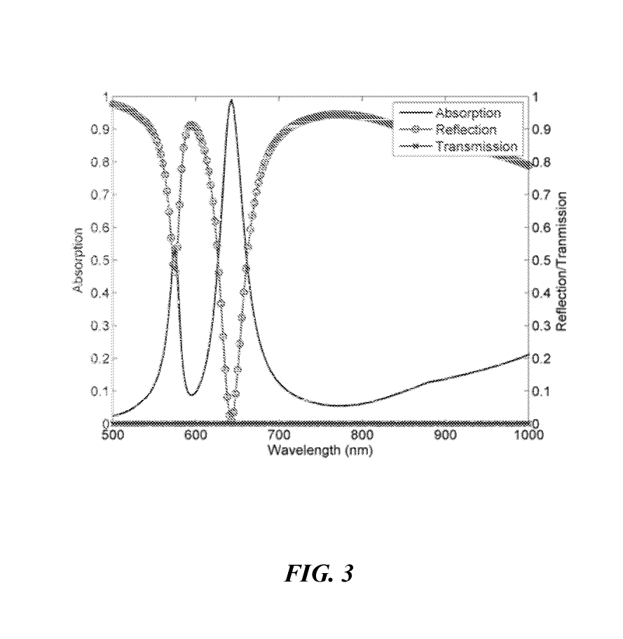

Combined responses of the top conductor layer 101 and bottom conductor layer 102 can result in a resonant electric response to impinging light from the direction of the top conductor layer 101. These electric resonances also excite current loops that form magnetic resonances. See, e.g., J. Hao, J. Wang, X. Liu, W. J. Padilla, L. Zhou, and M. Qiu, “High performance optical absorber based on a plasmonic metamaterial,” Applied Physics Letters, vol. 96, no. 25, p. 251104, 2010, which is entirely incorporated herein by reference. FIG. 3 is a computer simulation around the device of FIGS. 2a and 2b, which shows the absorption, reflection and transmission for one configuration optimized for visible wavelengths of light.

With reference to FIGS. 2a and 2b, the excitation of electric and magnetic resonances enables the absorption of substantially all of the light that is incident on the top conductor layer 101. The top conductor layer 101 includes pillars. The plasmon excitation in the top conductor layer 101 (see FIG. 2b) can decay to hot electrons 105 which can be transported into the semiconductor layer 103 via internal photoemission before they are thermalized and converted to heat in the top conductor layer 101. The thickness of the semiconductor layer 103 (i.e., a distance along a vector oriented from the top conductor layer 101 to the bottom conductor layer 102) can be a function of at least the index of refraction and electrical resistance of the semiconductor layer 103. The semiconductor layer 103 can have a thickness 107 from about 1 nanometer (nm) to 2000 nm, 1 nm to 1000 nm, 1 nm to 500 nm, 1 nm to 400 nm, 1 nm to 300 nm, 1 nm to 200 nm, 1 nm to 100 nm, 1 nm to 50 nm, or 1 nm to 10 nm. In some examples, such as for visible light applications, the semiconductor layer 103 has a thickness 107 from about 1 nm to 100 nm, or 1 nm to 50 nm. In other examples, the semiconductor layer 103 has a thickness 107 from about 20 nm to 500 nm, or 20 nm to 150 nm. For infrared (IR) light and longer wavelengths of light, the semiconductor layer 103 can have a thickness 107 from about 50 nm to 800 nm, or 100 nm to 400 nm. The thickness of the semiconductor layer 103 can be dependent on the material used and the desired collection wavelength.

The geometry of the top contact layer 101 can be selected or otherwise provided such that hot carriers are generated within one mean free path of the Schottky contact for efficient operation. In some examples, the top contact layer 101 has a cross-section that is circular, triangular, square, rectangular, pentagonal, hexagonal, heptagonal, octagonal, or partial shapes or combinations thereof.

The wavelength sensitivity can be dependent on one or more of (1) pitch 110 of the device, which can be the mean distance between adjacent top contact layers (see FIG. 2a), (2) the ratio between the width 106 and thickness 107 of pillars of the top conductor layer 101, and (3) the thickness 108 of the semiconductor layer 103. In an example, for visible light the width 106 and thickness 107 are from about 1 nm to 1000 nm, or 20 nm to 500 nm, and the ratio of pitch 110 to width 106 ranges from about 1 to 10, or 1.5 to 5. In some situations, the higher the ratio between the width and thickness, the longer the wavelength for complete or substantially complete absorption of incident light. For longer wavelength absorption, such as for IR sensing, the overall dimensions can be larger compared to visible light sensing.

The bottom conductor layer 102 can either (a) form an ohmic contact with the semiconductor layer 103, or (b) form a Schottky barrier with the semiconductor layer 103 if a lateral ohmic contact 104 is used. In some examples, the bottom conductor layer 102 is selected or otherwise configured to form a resonance with the top conductor layer 101 to increase absorption. The benefit of choosing a conductor that forms an ohmic contact with the semiconductor layer 103 is that it reduces the distance traveled through the semiconductor 103, thereby minimizing thermal losses.

An ohmic contact can be obtained when there is negative or no barrier to the flow of electrons from a semiconductor to a metal. The thickness of the bottom conductor layer 102 can be such that an ohmic contact with the semiconductor 103 is provided. The bottom conductor layer 102 in some cases is thin enough to not form a resonance at the frequencies of light of interest. In some cases, a third conductor layer can be provided above the bottom conductive layer 102 to create an Ohmic contact with the semiconductor layer. The material properties of the bottom conductor layer 102 may be similar to the materials used in the lateral contact 104. The third conductor layer can be provided to match boundary conditions, such as to match crystalline structures between material layers. The thickness of the bottom conductor layer 102 in such a case can be selected such that the third conductor layer does not form resonances upon light incident on the top conductor layer 101.

In cases in which a lateral ohmic contact 104 is provided (option (b) above), the optical absorption of the device of FIGS. 2a and 2b can be tailored without an intermediate conducting layer. The bottom conductor layer 102 can form a Schottky barrier with the semiconductor layer 103.

The top conductor layer 101 can include one or more of Au, Ag, Al, Cu, Pt, Pd, Ti, indium tin oxide (ITO), Ru, Rh, or graphene. The top conductor layer 101 can include nanoparticles, such as, for example, nanoparticles of Au, Al, Ag, Cu, Pt, Pd, Ti, Pt, or combinations thereof, which may be embedded in a composite matrix. The semiconductor layer 103 can be formed of an n-type or p-type semiconductor, and can form a Schottky barrier with top conductor layer 101. The semiconductor layer 103 can include one or more semiconducting or insulating material, such as Group II-VI material, Group III-V materials, and Group IV material. In some examples, the semiconductor layer 103 includes one or more of TiOₓ (e.g., TiO₂), SnOₓ (e.g., SnO₂), ZnO, silicon, carbon (e.g., diamond), germanium, SiC and GaN. These can be used to create Schottky barriers in depending upon the energy of the hot electrons in the plasmon excitation. The bottom conductor layer 102 can include one or more of Au, Ag, Al, Cu, Pt, Pd, Ti, ITO, Ru, Rh, Mn, Mg, C and graphene. In some examples, the bottom conductor layer 102 is formed of Ti for visible light applications. The lateral ohmic contact 104 can be formed of Au, Ag, Al, Cu, Pt, Pd, Ti, ITO, Ru, Rh, Mn, Mg, C and graphene or combinations (e.g., alloys thereof).

The top conductor layer 101 of FIGS. 2a and 2b can have various shapes and configurations. In some cases, for instance, the top conductor layer 101 can be provided in a crossbar configuration. The top conductor layer 101 can include one or more openings extending through the top conductor layer 101 and exposing portions of the semiconductor layer 103. In the illustrate example of FIG. 2a, the top conductor layer 101 includes rows separated from one another by spaces, which spaces define openings extending to the semiconductor layer 103. The spaces (or openings) can be under vacuum or filled with a gas, such as an inert gas (e.g., He, Ar). In some cases, the spaces can be filled with an electrically insulating material, such as a dielectric material.

The openings in the top conductor layer 101 can have various shapes and configurations. The openings can have cross-sections that are circular, triangular, square, rectangular, pentagonal, hexagonal, heptagonal, octagonal, or partial shapes or combinations thereof The openings can extend through at least a portion of the top conductor layer 101. In some cases the openings extend through only a portion of the top conductor layer 101, while in other cases the openings extend substantially through the top conductor layer 101 and expose portions of the semiconductor layer 103.

The openings can have a pitch from about 1 nm to 5000 nm, 10 nm to 5000 nm, 100 nm to 5000 nm, 200 nm to 5000 nm, or 400 nm to 2500 nm. An opening can have a width (e.g., distance between adjacent features of the top conductor layer 101) from about 1 nm to 2000 nm, 10 nm to 2000 nm, 100 nm to 2000 nm, or 100 nm to 300 nm.

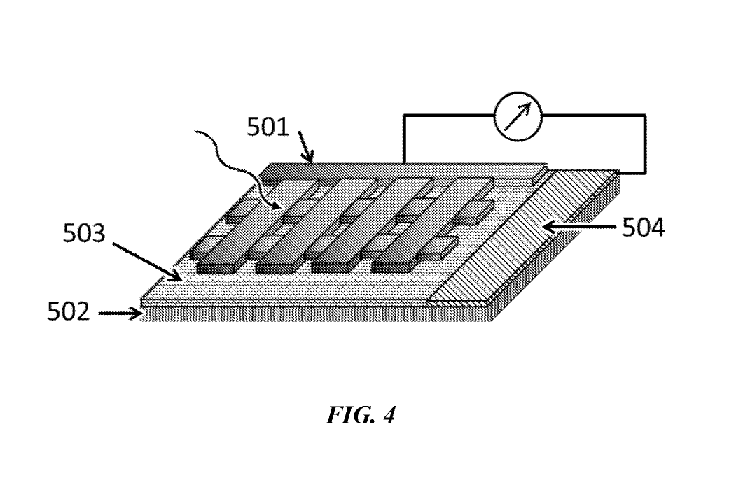

FIG. 4 schematically illustrates a light collection device having a crossbar configuration. The device of FIG. 4 includes a top conductor layer 501, a bottom conductor layer 502, a semiconductor layer 503 that is disposed between the top conductor layer 501 and the bottom conductor layer 502, and a lateral conductor 504 that is in contact with the semiconductor layer 503 and the bottom conductor layer 502. The lateral conductor 504 can form an ohmic contact with the semiconductor layer 503. The device of FIG. 4 can include openings (or holes) in the top conductor layer 501. These openings may determine the wavelength(s) of the plasmonic resonance states and hence the optical absorption at that wavelength. The geometry of the openings may determine the wavelength of light that is absorbed. The openings can expose portions of a surface of the semiconductor layer 503. The openings can be defined by features of the top conductor layer 501. In the illustrated example, the openings are each of square or rectangular cross section, bounded on all sides by features (e.g., cross-bars) of the top conductor layer 501.

In some embodiments, the top conductor layer 501 includes one or more conducting materials selected from Al, Ag, Au, Cu, Ni, Pt, and Pd. The top conductor layer 501 can be covered by a transparent electrode (not shown), which can be formed of one or more of ITO, silver, graphene, fluorine doped tin oxide (FTO), doped zinc oxide, carbon nanotubes in organic medium or other conducting transparent or near transparent materials. The transparent electrode can be provided as a continuous sheet or one or more nanostructures (e.g., nanowires). These configurations also exhibit symmetry and therefore will enable both angle independent and polarization independent response.

In an alternative configuration, the top layer may not be nanopatterned at all and in such case the configuration may support Fabry-perot resonances between the top metal layer and bottom metal layer. Wavelength sensitivity in this case can be obtained by the changing the thickness or refractive index of the semiconductor layer 503. Fabry-perot resonances in this configuration can generate hot electrons in the top conductor layer 501.

In some examples, modulating the index of refraction of surrounding medium through electro-optics, acousto-optics, or liquid crystals can change the optical response as a function of wavelength, creating a tunable collector of electromagnetic energy, such as, for example, a detector or other sensor. In this configuration the modulation can be controlled by a time varying input signal, from an acoustic, optic and/or electrical signal enabling a dynamically controllable collector. In some examples, wavelength tunable detection can be achieved by stretching or compressing the top and bottom conductor layers 501, 502 using an electric/optical to mechanical motion conversion mechanism.

As an alternative, multiple sensors can be configured in an array such that each sensor generates a unique signal specific to its location and the incident light intensity and wavelength at that location. In some cases, the bottom conductor 102 of FIG. 2 is isolated from other sensors in an array. An additional thin isolating tunneling insulator followed by a sensing gate can be provided over the bottom conductor 102 and away from the semiconductor 103. In some cases, the tunneling insulator is an oxide, such as a metal or semiconductor oxide (e.g., SiO₂ or TiO₂). The gate can measure the charge on the bottom conductor and can enable the conductor 102 to discharge when the sensor is read. In this configuration the sensors would create a wavelength specific array sensor.

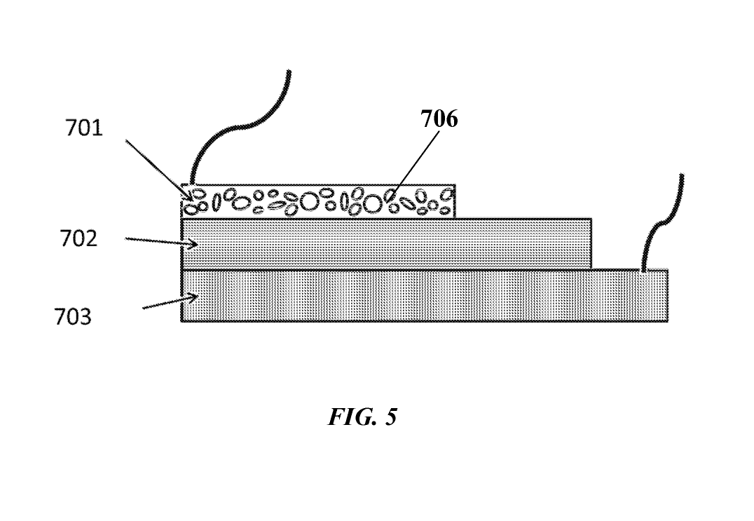

FIG. 5 shows an alternative electromagnetic radiation collector. In the configuration of FIG. 5, a top conductor layer 701 is a composite layer comprising isolated conducting nano/micro particles 706 embedded in the top conductor layer 701. The collector of FIG. 5 can be used with or modified by other devices or collectors herein. In some examples, the particles 706 are nanoparticles with particle sizes (e.g., widths, diameters) on the order of about 0.1 nm to about 1000 nm. In some cases, the nanoparticles have particle sizes from about 1 nm to 1000 nm, 1 nm to 500 nm, 1 nm to 100 nm, or 1 nm to 50 nm. In other examples, the particles 706 are microparticles, having particle sizes on the order of 1 micrometer (“micron”) to 1000 microns. In other examples, the particles 706 are both nano and microparticles. The top conductor layer 701 can be transparent. The conducting particles 706 can create localized surface plasmon resonances and resonantly interact with a bottom conducting layer 703. In an example, the top conductor layer 701 is comprised of metallic nanoparticles embedded in a conductor or semiconductor matrix. The matrix can be a composite matrix. The matrix can be a conducting matrix. The particles 706 can include one or more of Al, Pd, Ag, Au, Cu, Pt, Ni, Cu, Fe, W, yttrium oxide, palladium oxide, graphite and graphene. The top conductor layer 701 can have a thickness from about 1 nm to 1000 nm, or 20 nm to 500 nm. The materials that can be used for the semiconductor matrix can be n or p-type semiconductors. The matrix can include one or more of TiOx (e.g., TiO₂), SnOx (e.g., SnO₂), ZnO, other semiconductor oxides, Si, diamond, Ge, SiC, GaN, ZnO, Group III-V, Group II-VI and Group V materials. The particles 706 can be embedded in the matrix that forms the top conductor layer 701. The material that can be used for the semiconductor layer 702 can be n-type or p-type semiconductor material. The semiconductor layer 702 can form a Schottky barrier with the top conductor layer 701. The semiconductor layer 702 can be formed of one or more of TiOx (e.g., TiO₂), SnOx (e.g., SnO₂), ZnO, Si, diamond, Ge, SiC, GaN, ZnO, or Group III-V, Group II-VI or Group IV materials, or other metal oxides or semiconductor oxides. In an example, the top conductor 701 comprises a nanocomposite including Au/TiOx and has a thickness less than about 40 nm. The metal particles in the nanocomposite can create a Schottky barrier with the semiconductor layer 702 and possibly between the plasmonic nanoparticles and the matrix material for the nanocomposite layer itself Increasing the fill factor (or concentration) of the metal nanoparticles in the top conductor layer 701 at the interface with the semiconductor layer 702 can allow for insulators, such as SiOx or aluminum oxide (AlOx), to be used in the matrix while still creating a Schottky barrier with the semiconductor layer 702. The semiconductor layer 702 is in ohmic contact with a bottom conducting contact 703. This configuration can allow for absorption of a broad spectral range. See, e.g., M. K. Hedayati, M. Javaherirahim, B. Mozooni, R. Abdelaziz, A. Tavassolizadeh, V. S. K. Chakravadhanula, V. Zaporojtchenko, T. Strunkus, F. Faupel, and M. Elbahri, “Design of a perfect black absorber at visible frequencies using plasmonic metamaterials.,” Advanced materials (Deerfield Beach, Fla.), vol. 23, no. 45, pp. 5410-4, December 2011, which is entirely incorporated herein by reference.

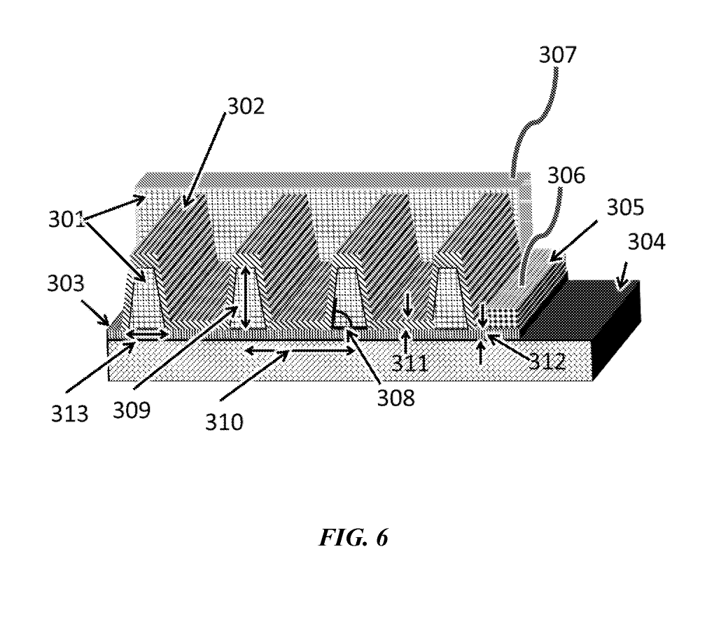

FIG. 6 shows a broadband absorption device structure. The device of FIG. 6 includes a top conductor layer 301, a semiconductor coating layer 302, a semiconductor layer 303, a bottom conductor layer 304, lateral Ohmic contact 305, contact wires 306 and 307. The device of FIG. 6 is similar in at least some respects to the device of FIG. 2, with the exception that the height of the top conductor layer 301 is extended to create high aspect ratio (i.e., height to width) nanostructures or pillars. The pillars can be three-dimensional pillars. This configuration can create hybridized cavity-surface plasmon resonances between “pillars” for a broader absorption spectrum. Such a structure may broaden the absorption spectrum. See, e.g., C.-hung Lin, R.-lin Chem, and H.-yan Lin, “Nearly perfect absorbers in the visible regime,” Optics Express, vol. 19, no. 2, pp. 686-688, 2011, which is entirely incorporated herein by reference.

These high aspect ratio pillars create cavity resonances that also interact with the bottom metal film through Fabry-Perot resonances. The performance of the broadband absorber can be varied and optimized by tuning the aspect ratio or taper angle 308 of the Pillar as shown in FIG. 6. The size of the top conductor layer 301 is tailored for the electromagnetic spectrum to be collected. In some examples, for visible light harvesting the height 309 of the pillars is in the range of about 100 nm to 2000 nm, or 300 nm to 1000 nm; the width 313 of the pillars is in the range of about 100 nm to 2000 nm, or 100 nm to 300 nm; and the pitch 310 is in the range of about 200 nm to 5000 nm, or 400 nm to 2500 nm. In some examples, the pillars have an aspect ratio (i.e., height to width) of at least about 1:1, 2:1, 3:1, 4:1, 5:1, 6:1, 7:1, 8:1, 9:1, 10:1, 11:1, 12:1, 13:1, 14:1, 15:1, 16:1, 17:1, 18:1, 19:1, or 20:1. In the embodiment shown in FIG. 6, a conformal coating of semiconductor 302 is deposited on the top and sides of the pillars to minimize the distance between the region where hot electrons are created and the Schottky barrier. That distance should be less than the mean free path of the hot electrons in the metal for efficient operation. For visible light collection, the thickness 311 of the semiconductor layer 302 can ranges from about 1 nm to 800 nm, 1 nm to 500 nm, 1 nm to 400 nm, 1 nm to 300 nm, 1 nm to 200 nm, 1 nm to 100 nm, or 1 nm to 50 nm; however, thicker layers can be used. Thinner layers below about 5 nm in thickness can require smooth surfaces to prevent defects in the semiconductor that may generate shorting over time from material migration. The semiconductor layer 303 is positioned between the top conductor layer 301 and the bottom conductor layer 304. The materials that can be used for the semiconductor layer 302 and 303 can be n-type or p-type; the material of each semiconductor layers 302 and 303 can be selected to form a Schottky barrier with top conductor layer 301. The semiconductor layers 302 and 303 can be formed of one or more of TiOx (e.g., TiO₂), SnOx (e.g., SnO₂), ZnO, Si, diamond, Ge, SiC, GaN, ZnO, or Group III-V, Group II-VI or Group IV materials, or other metal oxides or semiconductor oxides. A taper angle 308 can be greater than about 10 degrees, 20 degrees, 30 degrees, 40 degrees, 45 degrees, 50 degrees, 55 degrees, 60 degrees, 65 degrees, 70 degrees, 75 degrees, 80 degrees, or 85 degrees. In some cases, the taper angle 308 can be between about 50 degrees and 90 degrees, or 70 degrees and 90 degrees. The device of FIG. 6 can have a cross-hatch configuration similar to that shown in FIG. 4, which can provide further polarization and angle independence.

The semiconductor layer 303 can have a thickness 312 from about 1 nanometer (nm) to 1000 nm, 1 nm to 100 nm, or 1 nm to 50 nm. In some examples, the semiconductor layer 303 has a thickness 312 from about 20 nm to 500 nm, or 20 nm to 150 nm. In some examples, for optical absorption the thickness 312 is below 100 nm.

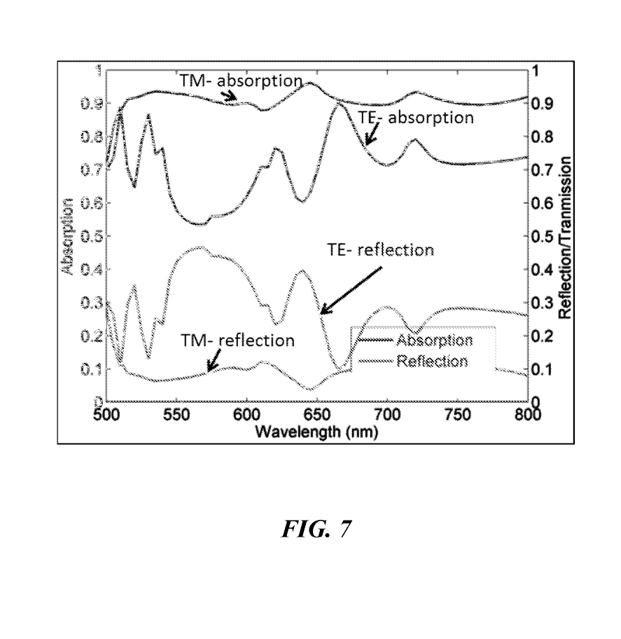

FIG. 7 is a computer simulation showing optical absorption, reflection and transmission of the device of FIG. 6 that can be optimized for visible wavelengths. The device shows wide band and polarization (transverse-electric and transverse-magnetic) independent absorption of light.

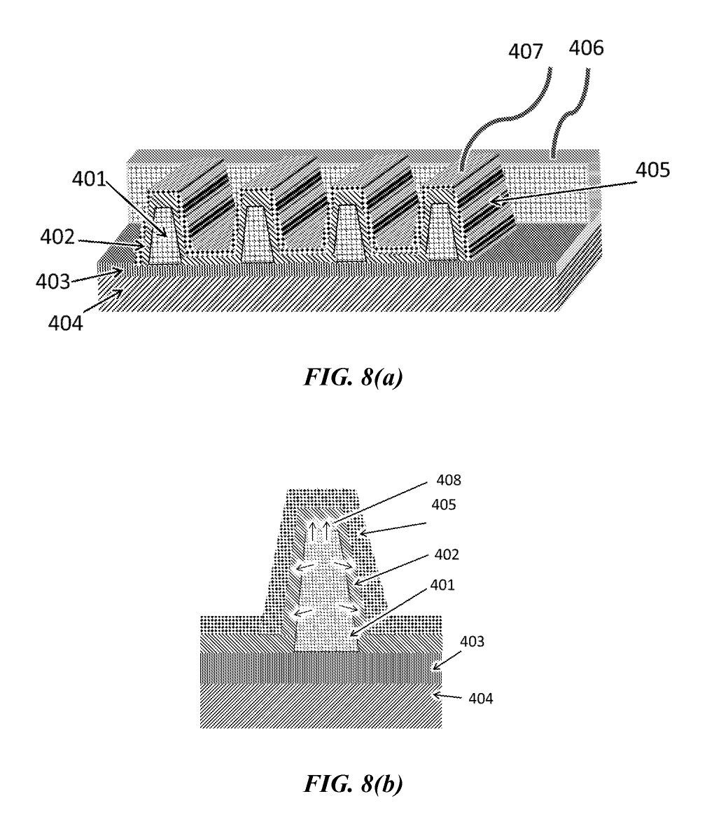

FIGS. 8a and 8b show another electromagnetic radiation collector. FIG. 8b is a close-up on a pillar of FIG. 8a. The device of FIGS. 8a and 8b comprises a top conductor layer 401, first semiconductor layer 402, second semiconductor layer 403, bottom conductor layer 404, transparent conductor layer 405, a first (electrical) contact test point 406 and a second contact test point 407. The transparent conductor layer 405 forms an ohmic contact with the first semiconductor layer 402. Hot electron paths 408 have been indicated in FIG. 8b; the hot electron paths 408 are from the top conductor layer 401 through the first semiconductor layer 402 and into the transparent conductor layer 405. The transparent conductor layer 405 can include any material that is transparent to select wavelengths of light. For visible and near IR, the transparent conductor layer 405 can include, but is not limited to, ITO, silver nanowires, doped ZnO, graphene or other suitable materials. The thickness of the transparent conductor layer 405 can be from about 10 nm to 500 nm, or 50 nm to 150 nm. The thickness can be selected such that the device of FIGS. 8a and 8b generates power upon exposure to light while being transparent to incident light. The bottom conductor layer 404 can be floating or, alternatively, electrically coupled to another electrical contact point for sensing or control applications. In an example, the top conductor layer 401 and bottom conductor layer 404 can each include one or more of Au, Ag, Al, Cu, Sn, Ni, Pt, Pd, Ti, ITO, Ru, Rh, and graphene, or in combination with other materials. In some examples, the top conductor layer 401 or bottom conductor layer 404 includes a SnNi alloy or Ag/Al. The material and/or thickness of the second semiconductor layer 403 can be selected to shorten the electron path through the second semiconductor layer 403. The transparent top conductor layer 405 can be connected to the second contact test point 407 and the top conductor layer 401 can be connected to the first contact test point 406. The first and second contact test points 406 and 407 can be formed of electrical conductors, as described elsewhere herein.

In some cases, the top transparent conductor layer 405 can be opaque to a desired portion of the electromagnetic spectrum, effectively filtering out desired frequencies of light while enabling other frequencies of light to penetrate into the collector. In this configuration, the device can operate as a broad spectrum sensor and energy collector tailored to a desired electromagnetic spectrum. This could enable self-powering sensors or filtering undesired light. For example, the material properties of the top transparent conductor layer 405 can be selected such that a portion of incident light comes in contact with the top conductor layer 401 to generate electrons, which electrons are used to power the device and provide sensing capabilities.

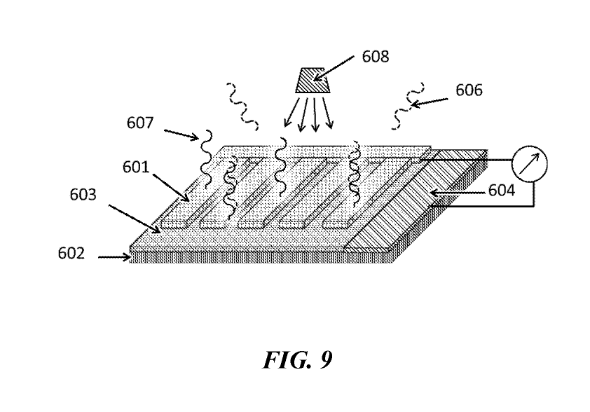

This disclosure provides devices that can be used as biological and/or chemical sensors. With reference to FIG. 9, a device for real-time, label-free detection of biomolecule sensing is shown. The device of FIG. 9 can be used to sense, detect or monitor binding events between complimentary biomolecules, such as, without limitation, oligonucleotides and antibody/antigens, such as, for example, by changes in power generation or current flow across the device.

The device of FIG. 9 includes a top conductor layer 601, bottom conductor layer 602, semiconductor layer 603 between the top conductor layer 601 and bottom conductor layer 602, and a lateral contact 604 (e.g., ohmic contact). The top conductor layer 601 can be a nanostructured top metal layer, as described elsewhere herein. A load is coupled to the top conductor 601 and the lateral contact 604. The device includes a light source 608 that delivers light to the top conductor 601 and semiconductor layer 603. The light can have a known frequency (or wavelength) and intensity.

The device of FIG. 9 is adapted to come in contact with a solution comprising one or more analytes. The device can include a flow cell to deliver the solution to the top conductor 601.

In an example, during operation of the device of FIG. 9, signal transduction can occur when target molecules 606 in solution come in close proximity to (or contact with) probe molecules 607 bound to the surface of the top conductor 601 of the device, allowing for complimentary reactions to occur. The buildup of complimentary target molecules on the surface of probe molecule can cause a change in refractive index of the surrounding medium of the nanostructured top metal layer 601, which in turn can modulate the amount of power generated in and/or current flow through the device as driven by the light source 608 of known wavelength and intensity. When proper experimental controls and procedures, familiar to those skilled in the art, are applied, detection of target biomolecules in complex solution-based samples is possible.

The device of FIG. 9 can be configured as a chemical sensor for gases and vapors. In an example, when gases/vapors are present in the surrounding medium of the nanostructured top metal conductor 601 or absorbed into the nanostructured top metal conductor 601, semiconductor 603 or bottom conductor 602 the refractive index and/or geometry can be changed. This, in turn, can modulate the power generated in and/or current flowing through the device as driven by a light of known wavelength and intensity from the light source 608. In an example, the device can be used to detect mercury (Hg) through its reaction with gold (Au).

An electromagnetic energy collection system can include one or more electromagnetic energy collection devices described above or elsewhere herein. In cases in which the system includes a plurality of electromagnetic energy collection devices, individual devices can be coupled to one another in series or in parallel. In an example, individual electromagnetic energy collection devices are coupled in series by electrically connecting a bottom conductor layer of a first electromagnetic energy collection device to a top conductor layer of a second electromagnetic energy collection device, and electrically connecting a bottom conductor of the second electromagnetic energy collection device to an external load or to a top conductor of a third electromagnetic energy collection device. A top conductor of the first electromagnetic energy collection device can be electrically coupled to a bottom conductor of a fourth electromagnetic energy collection device or to the external load.

### Methods for Forming Devices

Another aspect of the disclosure provides a method for forming a device that is adapted to collect electromagnetic radiation (or energy). The method can include forming a semiconductor layer adjacent to a surface of a first metallic layer, and forming a lateral contact adjacent to the semiconductor layer and the first metallic layer. A second metallic layer can then be formed adjacent to the semiconductor layer.

In some examples, the device is formed by vapor phase delivery methods. In some examples, the device is manufactured by sputtering. In this case, both the semiconductor and the metal can be deposited using one chamber, which may decrease manufacturing time. As an alternative, separate chambers may be used. In some cases, the electromagnetic radiation collection device is formed in a vacuum chamber or an inert environment (e.g., Ar or He background) using one or more vapor phase delivery techniques. In other examples, the device can be formed through solution delivery methods. In other examples, the device can be formed through a combination of vapor phase and solution delivery methods.

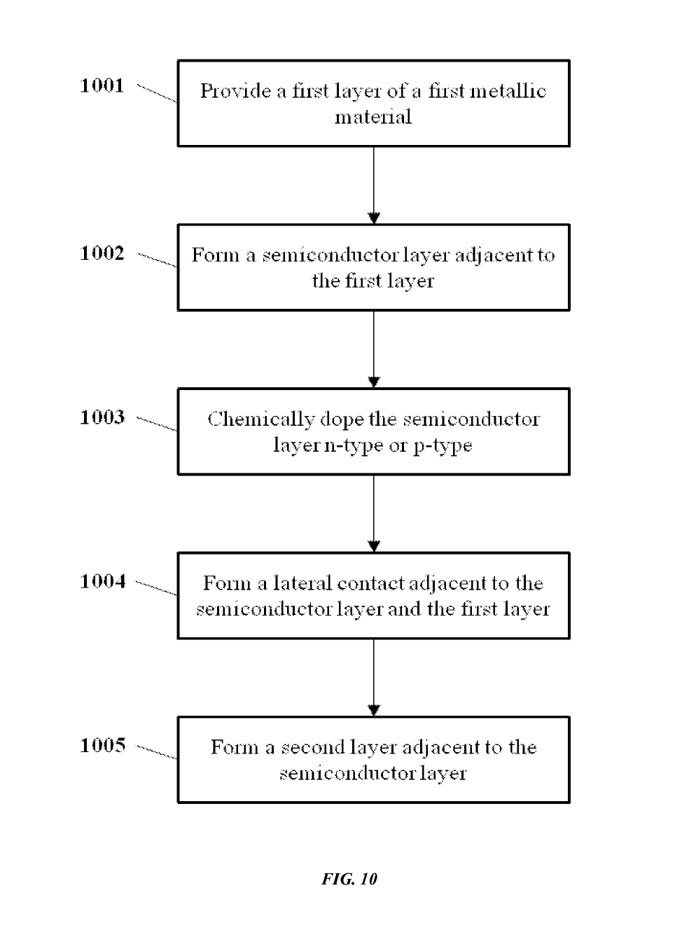

With reference to FIG. 10, in a first operation 1001, a first layer of a first metallic material is provided. The first metallic material can be provided on a substrate holder or susceptor. In some examples, the first layer is provided as a substrate in a reaction chamber (or reactor) having a reaction space for accepting various precursors for forming devices of the disclosure. The first layer can be a continuous sheet of the first metallic material, such as gold. The first metallic material can be selected to form a Schottky contact with a semiconductor material, as described elsewhere herein. The first layer can be cleaned, such as with the aid of an acidic solution and/or an oxidizing agent. In an example, the first layer is cleaned with the aid of H₂SO₄ and H₂O₂.

Next, in a second operation 1002, a semiconductor layer is formed adjacent to the first layer. In some examples, the semiconductor layer is formed directly on the first layer. The semiconductor layer can be formed by depositing the semiconductor layer on the first layer, such as by using a vapor deposition technique. Examples of vapor phase deposition techniques include atomic layer deposition (ALD), chemical vapor deposition (CVD), or physical vapor deposition (PVD), or variants thereof, such as, for example, plasma-enhanced ALD or plasma-enhanced CVD. In an example, the semiconductor layer includes silicon, which is deposited by bringing the first layer in contact with Si₂H₆ at a temperature (of the first layer) from about 500° C. to 900° C.

Next, in a third operation 1003, the semiconductor layer is chemically doped n-type or p-type. In an example, the semiconductor layer is doped n-type with the aid of a precursor of an n-type chemical dopant. The precursor can include NH₃ or PH₃. If the semiconductor layer is intended to be doped p-type, then a precursor of a p-type chemical dopant can be used, such as, for example, B₂H₆.

The semiconductor layer can be doped by exposing the first layer to a precursor of an n-type or p-type chemical dopant while the semiconductor layer is being deposited on the first layer, or after the semiconductor layer is formed adjacent to the first layer. In some cases, if doping is to be performed after the semiconductor layer is formed, then the semiconductor layer can be exposed to a precursor of the n-type or p-type chemical dopant and concurrently or subsequently annealed to drive the n-type or p-type chemical dopant into the semiconductor layer.

As an alternative, the semiconductor layer can be doped n-type or p-type after the semiconductor layer is formed adjacent to the first layer. In an example, the semiconductor layer can be doped n-type or p-type by ion implantation.

Next, in a fourth operation 1004, a lateral contact is formed adjacent to the semiconductor layer and the first layer. The lateral contact can include a material that forms an ohmic contact with the semiconductor layer. In an example, the lateral contact is formed by removing a portion of the semiconductor layer, such as with the aid of photolithography. For instance, the semiconductor layer can be covered with a photoresist (e.g., poly(methyl methacrylate), poly(methyl glutarimide), phenol formaldehyde resin) and an edge portion of the semiconductor layer can be exposed and developed, and subsequently removed (e.g., using a rinse/wash) to provide a mask. Next, an anisotropoic etch (e.g., KOH) can be used to etch the semiconductor layer to the first layer to expose a lateral portion of the first layer. Next, the lateral contact can deposited adjacent to the first layer and the semiconductor layer, such as, for example, with the aid of a vapor phase deposition technique (e.g., PVD). In an example, the lateral contact is a silicide that is formed by exposing the first layer to a silicon precursor (e.g., Si₂H₆) and a carbon precursor (e.g., CH₄) to form the silicide adjacent to the first layer and the semiconductor layer. The lateral contact can be formed at a temperature from about 500° C. to 900° C.

Following formation of the lateral contact, the mask adjacent to the semiconductor layer can be removed, such as, for example, by exposing the mask to an isotropic chemical etchant (e.g., HF, HNO₃, H₂SO₄) or using chemical-mechanical planarization (CMP). The nascent device can now include the first layer and the semiconductor layer and lateral contact adjacent to the first layer.

Next, in a fifth operation 1005, a second layer is formed adjacent to the semiconductor layer. The second layer can be formed of a second metallic material that forms a Schottky contact with the semiconductor layer. The second layer can be formed by providing a photoresist over the semiconductor layer and the lateral contact, exposing the semiconductor layer through the photoresist to provide a mask that covers the lateral contact. The second metallic material can then be deposited over the semiconductor layer to provide the second layer adjacent to the semiconductor layer. The second metallic material can be provided using a vapor phase deposition technique, such as PVD (e.g., sputter deposition). The mask can then be removed to provide the device having the second layer adjacent to the semiconductor layer, and the lateral contact exposed.

In cases in which the second metallic material is to be provided as elongate features (see, e.g., FIGS. 2a and 2b), then the mask in the fifth operation can be provided to expose portions of the semiconductor layer. For instance, the mask can cover the lateral contact and cover portions (but not all) of the semiconductor layer, and the second metallic material can be deposited. The second metallic material can deposit on exposed portions of the semiconductor layer.

In cases in which the second layer is to have the configurations of FIG. 6 or FIGS. 8a and 8b, then the deposition of the second layer can be tailored to provide the material of the second layer with desirable or otherwise predetermined aspect ratios. For instance, multiple mask application/deposition/mask removal operations can be employed to provide a second layer with high aspect ratio features.

Controllers and systems can be used to control and regulate the growth of electromagnetic radiation collection devices of the disclosure. In an example, a control system is provided to control various process parameters, such as, for example, substrate and/or substrate holder (or susceptor) temperature, reactor pressure, reaction space pressure, reaction chamber pressure, plasma generator pressure, the flow rate of gas (e.g., Si₂H₆) into a plasma generator, the flow rate of gas into a reaction space, the rate at which the substrate is moved from one reaction space to another, the rate at which the substrate rotates during thin film formation, power to a plasma generator (e.g., direct current or radio frequency power), and a vacuum system in fluid communication with the reaction chamber. The pressure of the reaction chamber can be regulated with the aid of a vacuum system. The vacuum system can comprise various pumps configured to provide vacuum to the reaction chamber, such as, e.g., one or more of a turbomolecular (“turbo”) pump, a cryopump, an ion pump and a diffusion pump, in addition to a backing pump, such as a mechanical pump.

Devices, systems and methods of the disclosure may be combined with or modified by other devices, systems and methods, such as those described in E. W. McFarland and J. Tang, “A photovoltaic device structure based on internal electron emission,” Nature, vol. 421, no. 6923, pp. 616-8, February 2003; U. Kreibig and M. Vollmer, Optical Properties of Metal Clusters. Springer, 1995; R. Kostecki, S. Mao, “Surface Plasmon-Enhanced Photovoltaic Device,” U.S. Patent Pub. No. 2010/0175745 A1; M. W. Knight, H. Sobhani, P. Nordlander, and N. J. Halas, “Photodetection with active optical antennas,” Science (New York, N.Y.), vol. 332, no. 6030, pp. 702-4, May. 2011; Y. Lee, C. Jung, J. Park, H. Seo, and G. Somorjai, “Surface Plasmon-Driven Hot Electron Flow Probed with Metal-Semiconductor Nanodiodes,” Nano Letters, vol. 11, no. 10, pp. 4251-5, October 2011; J. Hao, J. Wang, X. Liu, W. J. Padilla, L. Zhou, and M. Qiu, “High performance optical absorber based on a plasmonic metamaterial,” Applied Physics Letters, vol. 96, no. 25, p. 251104, 2010; M. K. Hedayati, M. Javaherirahim, B. Mozooni, R. Abdelaziz, A. Tavassolizadeh, V. S. K. Chakravadhanula, V. Zaporojtchenko, T. Strunkus, F. Faupel, and M. Elbahri, “Design of a perfect black absorber at visible frequencies using plasmonic metamaterials.,” Advanced materials (Deerfield Beach, Fla.), vol. 23, no. 45, pp. 5410-4, December 2011; and C.-hung Lin, R.-lin Chem, and H.-yan Lin, “Nearly perfect absorbers in the visible regime,” Optics Express, vol. 19, no. 2, pp. 686-688, 2011, each of which is entirely incorporated herein by reference.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents. It is intended that the following claims define the scope of the invention and that methods and structures within the scope of these claims and their equivalents be covered thereby.

What is claimed is:

1. A device for collecting electromagnetic energy, comprising:
(a) a first layer comprising electrically conductive nanostructures, wherein the first layer is adapted to generate hot electrons upon exposure to electromagnetic energy;
(b) a second layer adjacent to said first layer, wherein said second layer comprises a semiconductor material, and wherein an interface between said first and second layers comprises a Schottky barrier to charge flow upon exposure of said device to electromagnetic energy; and
(c) a third layer adjacent to said second layer, wherein said third layer comprises an electrically conductive material,
wherein, upon exposure of said device to electromagnetic energy, said nanostructures in said first layer generate localized surface plasmon resonances that resonantly interact with said third layer to produce power.

2. The device of claim 1, wherein, upon exposure of said device to electromagnetic energy, combined responses of said first layer and said third layer results in resonant electric and magnetic responses to impinging electromagnetic energy from the direction of the first layer.

3. The device of claim 1, wherein said third layer forms a Schottky contact with said second layer.

4. The device of claim 3, further comprising an electrode that is adjacent to said second and third layers, wherein said electrode is laterally adjacent to said second layer, and wherein said electrode forms an ohmic contact with said second layer.

5. The device of claim 1, wherein said third layer forms an ohmic contact with said second layer.

6. The device of claim 5, further comprising a fourth layer adjacent to said third layer, wherein said fourth layer forms electric and magnetic resonances with said first layer.

7. The device of claim 1, wherein said electrically conductive nanostructures of said first layer and/or said electrically conductive material of said third layer include one or more materials selected from the group consisting of aluminum, silver, gold, copper, platinum, nickel, copper, iron, tungsten, yttrium oxide, palladium oxide, graphite and graphene.

8. The device of claim 1, wherein said semiconductor material includes one or more materials selected from the group consisting of titanium oxide, tin oxide, zinc oxide, silicon, diamond, germanium, silicon carbide, gallium nitride, cadmium telluride.

9. The device of claim 1, wherein said electrically conductive nanostructures of said first layer are included in a plurality of elongate rows.

10. The device of claim 1, wherein said electrically conductive nanostructures of said first layer are included in one or more three-dimensional pillars, wherein an individual pillar of said one or more three-dimensional pillars has a height to width ratio greater than one.

11. The device of claim 10, wherein said individual pillar has a taper angle between about 50 degrees and 90 degrees in relation to a base of said individual pillar.

12. The device of claim 10, wherein said individual pillar has an aspect ratio of at least about 2:1.

13. The device of claim 10, wherein said individual pillar has an aspect ratio of at least about 10:1.

14. The device of claim 1, wherein said first layer is optically transparent.

15. The device of claim 1, further comprising a fourth layer adjacent to said first layer, wherein said fourth layer comprises a semiconductor material.

16. The device of claim 1, wherein said first layer comprises one or more probe molecules adsorbed on an exposed surface of said first layer, wherein said one or more probe molecules are adapted to (i) interact with an analyte in a solution that is in contact with said first layer and (ii) modulate power generated in and/or current flow through the device.

17. The device of claim 1, wherein individual nanostructures of said electrically conductive nanostructures have particle sizes from about 1 nanometer (nm) to 100 nm.

18. The device of claim 1, wherein said first layer comprises a matrix, and wherein said electrically conductive nanostructures are embedded in said matrix.

19. The device of claim 18, wherein said matrix includes one or more materials selected from the group consisting of titanium oxide, tin oxide, zinc oxide, silicon, diamond, germanium, silicon carbide, gallium nitride, cadmium telluride.

20. The device of claim 1, wherein said second layer has a thickness from about 1 nanometer (nm) to 500 nm.

21. The device of claim 1, wherein said electrically conductive nanostructures are disposed in a patterned array in said first layer.

22. The device of claim 1, wherein said first layer comprises one or more openings extending through said first layer.

23. The device of claim 22, wherein portions of said second layer are exposed through said one or more openings of said first layer.

24. The device of claim 1, wherein said third layer is isolated from said first layer.

25. A system for collecting electromagnetic energy comprising one or more electromagnetic energy collection devices, an individual device comprising:
a first electrically conductive layer adjacent to a semiconductor layer, wherein said first electrically conductive layer forms a Schottky barrier to charge flow at an interface between said first electrically conductive layer and said semiconductor layer;
a second electrically conductive layer adjacent to said semiconductor layer and disposed away from said first electrically conductive layer, wherein said second electrically conductive layer forms (i) an ohmic contact with said semiconductor layer, or (ii) a Schottky barrier to charge flow at an interface between said second electrically conductive layer and said semiconductor layer,
wherein, upon exposure of said device to electromagnetic energy, said first electrically conductive layer generates localized surface plasmon resonances that resonantly interact with said second electrically conductive layer to produce power.

26. The system of claim 25, wherein said semiconductor layer has a thickness from about 1 nanometer (nm) to 500 nm.

27. The system of claim 26, wherein said semiconductor layer has a thickness from about 1 nm to 100 nm.

28. The system of claim 25, wherein said second electrically conductive layer forms a Schottky barrier to charge flow at said interface between said second electrically conductive layer and said semiconductor layer.

29. The system of claim 25, wherein said second electrically conductive layer forms an ohmic contact with said semiconductor layer.

30. The system of claim 25, wherein said system comprises a plurality of electromagnetic energy collection devices.

31. The system of claim 30, wherein said electromagnetic energy collection devices are electrically coupled to one another in series.

32. The system of claim 25, wherein, upon exposure of said system to electromagnetic energy, combined responses of said first electrically conductive layer and said second electrically conductive layer results in a resonant electric response to impinging electromagnetic energy from the direction of the first electrically conductive layer.

33. The system of claim 25, further comprising a contact that is adjacent to said semiconductor layer and said second electrically conductive layer, wherein said contact is laterally disposed in relation to said semiconductor layer, and wherein said contact forms an ohmic contact with said semiconductor layer.

34. The system of claim 25, wherein said first electrically conductive layer includes electrically conductive nanostructures.

35. The system of claim 34, wherein said electrically conductive nanostructures and/or said second electrically conductive layer include one or more materials selected from the group consisting of aluminum, silver, gold, copper, platinum, nickel, copper, iron, tungsten, yttrium oxide, palladium oxide, graphite and graphene.

36. The system of claim 34, wherein said electrically conductive nanostructures are included in a plurality of elongate rows.

37. The system of claim 34, wherein said electrically conductive nanostructures are included in one or more three-dimensional pillars, wherein an individual pillar of said one or more three-dimensional pillars has a height to width ratio greater than one.

38. The system of claim 37, wherein said individual pillar has a taper angle between about 50 degrees and 90 degrees in relation to a base of said individual pillar.

39. The system of claim 37, wherein said individual pillar has an aspect ratio of at least about 2:1.

40. The system of claim 37, wherein said individual pillar has an aspect ratio of at least about 10:1.

41. The system of claim 25, wherein said first electrically conductive layer comprises a composite matrix and nanostructures in said composite matrix.

42. The system of claim 41, wherein said nanostructures have particle sizes from about 1 nanometer (nm) to 100 nm.

43. The system of claim 41, wherein said composite matrix includes one or more materials selected from the group consisting of titanium oxide, tin oxide, zinc oxide, silicon, diamond, germanium, silicon carbide, gallium nitride, cadmium telluride.

44. The system of claim 25, wherein said semiconductor layer includes one or more materials selected from the group consisting of titanium oxide, tin oxide, zinc oxide, silicon, diamond, germanium, silicon carbide, gallium nitride, cadmium telluride.
